(19) United States
(12) Patent Application Publication
(10) Pub. No.: US 2013/0056704 A1
(43) Pub. Date: Mar. 7, 2013

(54) SINGLE-PHOTON GENERATOR AND METHOD OF ENHANCEMENT OF BROADBAND SINGLE-PHOTON EMISSION

(71) Applicants: Vladimir M. Shalaev, West Lafayette, IN (US); Eric Kochman, Highland Park, IL (US); Andrey N. Smolyaninov, Khimki (RU)

(72) Inventors: Vladimir M. Shalaev, West Lafayette, IN (US); Eric Kochman, Highland Park, IL (US); Andrey N. Smolyaninov, Khimki (RU)

(73) Assignee: Nano-Meta Technologies Inc.

(21) Appl. No.: 13/459,623

(22) Filed: Apr. 30, 2012

Related U.S. Application Data
(60) Provisional application No. 61/530,187, filed on Sep. 1, 2011.

(51) Int. Cl. H01L 33/06; B82Y 20/00

(52) U.S. Cl. 257/13; 257/E33.005; 977/950

(57) ABSTRACT

A single-photon generator contains nitrogen-vacancies or other color centers in diamond as emitters of single photons which are excited by the laser beam or another optical source and can work stably under normal conditions, the metamaterial with hyperbolic dispersion as enhancing environment, and photonic guiding structure to collect and transmit single photons further. Single photons generators are fundamental elements for quantum information technologies such as quantum cryptography, quantum information storage and optical quantum computing

### CROSS-REFERENCE TO RELATED APPLICATIONS

This patent application claims priority to U.S. Provisional application No. 61/530,187 filed on Sep. 1, 2011.

### FIELD OF INVENTION

The present application may relate to the use of optical metamaterials for enhancing the emission characteristics of single photon sources located thereon.

### BACKGROUND OF THE INVENTION

Single photons are the fundamental elements of quantum information technologies such as quantum cryptography, quantum information storage and optical quantum computing. The key directions of computer development today are to drastically increase the CPU operating frequency as well as to discover and implement mechanisms of high-performance parallel computing. Progress in this field could be made possible using optical technology and quantum computing algorithms. Practical implementation of these approaches demand effective stable sources of single photons and the nanostructures to control the quantum dynamics of these photons. The applications of the single-photon sources can benefit from an increased flux of single photons, which can be achieved by engineering the electromagnetic environment of the emitter. It has been already demonstrated that such enhancement could be accomplished by coupling emitters with photonic crystals and plasmonic cavities, creating monolithic architectures like solid immersion lenses and nanowires. However, there is still a need for increasing the single-photon flux in a broad spectral range, beyond the reach of the techniques used so far.

U.S. Pat. No. 7,554,080 disclosed a quantum computing system built on a single-photon light source based on NV defect in diamonds. However, there is still a need for increasing the single-photon flux in a broad spectral range, beyond the reach of the techniques used so far.

It was disclosed in the paper by Noginov et al. that hyperbolic materials are predicted to have broad-band singularity of photonic density of states, which causes enhanced and highly directional spontaneous emission and enables a variety of devices with new functionalities, including a single-photon gun (Proceedings of Lasers and Electro-Optics (CLEO) and Quantum Electronics and Laser Science Conference (QELS), 16 May 2010). Zubin et al. pointed out that metamaterials with hyperbolic dispersion may be used to enhance the single photon radiation (Frontiers in Optics (FiO); San Jose, Calif., Oct. 11, 2009).

Optical metamaterials are artificial materials arranged of structural elements with at least one dimension being less than a quarter wavelength of the incident light in vacuum. The present invention addresses implementation of the metamaterials for enhancement of photons flux generated by a single photon source.

### SUMMARY OF THE INVENTION

The present invention addresses a system for single-photon generation based on coupling diamond nitrogen-vacancy centers, or other impurity-vacancy color centers, such as silicon-vacancy center, with a metamaterial with hyperbolic dispersion and method of enhancement of single-photon emission by the metamaterial with hyperbolic dispersion. The preferable operating temperature of single photon source is from −35° C. to +50° C. The said nitrogen-vacancy or silicon-vacancy centers may be produced in diamond structures of various configurations. In one embodiment diamond structure is used in the form of diamond film on the metamaterial surface, wherein the maximum distance between nitrogen-vacancy in said diamond structure and the surface of metamaterial with hyperbolic dispersion is less than 1,000 nm in order to get enhancement of single-photon emission.

The metamaterial has uniaxial optical anisotropy, and in the preferred embodiment it is made by alternate layers of plasmonic and dielectric materials. At least one layer of said metamaterials is thinner than 100 nm Alumina may be used as dielectric material, and a variety of conducting materials may be implemented, for example, layers of silver, transparent conducting oxide, transition metal nitride, and others. The metamaterial is transverse positive with the optical axis being oriented normally to the material interface. The metamaterial provides the photon flux enhancement up to two orders of magnitude.

Another object of the present invention is a method for producing an enhanced emission of photon flux, which includes generating an initial flux and its enhancing at least 10 times in a hyperbolic metamaterial. The initial single photon flux is generated by a diamond structure with at least one impurity-vacancy color center, which is attached to the metamaterial by a spin coating procedure.

### BRIEF DESCRIPTION OF THE DRAWINGS

FIG. 1 shows a conceptual (a) perspective view; (b) side view; (c) top view of a single-photon generator of the present invention.

FIG. 2 shows iso-frequency surfaces in isotropic (a) and anisotropic media (b, c) with hyperbolic dispersion.

FIG. 3 shows geometry of a metal-dielectric multilayer composite with hyperbolic dispersion.

### DETAILED DESCRIPTION OF THE INVENTION

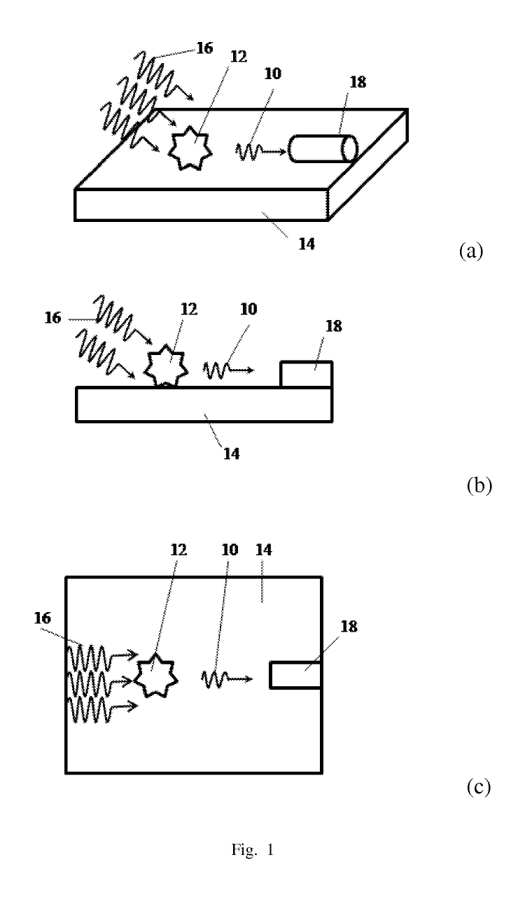

For the purposes of promoting an understanding of the principles of the present application, reference will now be made to the embodiments illustrated in the drawings, and specific language will be used to describe the same. It will nevertheless be understood that no limitation of the scope of this application is thereby intended. Referring now to the invention in more detail, in FIGS. 1(a), 1(b) and 1(c), there is shown a device generating single photons 10. The single-photon generator consists of a nanoparticle emitter 12 placed on metamaterial 14, excitation laser beam (or other pumping source) 16, and photonic guiding structure 18.

Alternatively, the single photon source may be pumped electrically, which is known to a person skilled in the art. The realization of a stable, electrically driven single-photon source based on a single neutral nitrogen-vacancy center in a diamond diode structure at room-temperature has been disclosed in the letter by Mizuochi et al., thus proving that functional single defects can be integrated into electronically controlled structures (Nature Photonics, published on-line Apr. 15, 2012).

In at least one embodiment, still referring to the invention, the single-photon generator works in the following way: the nanoparticle emitter 12, excited by the laser beam 16, generates single photons 10, which are subsequently collected and transmitted further by photonic guiding structure 18. The metamaterial 14 with hyperbolic dispersion is required for enhancing the single-photon emission in a broad wavelength range, as for example, the emission spectrum from nitrogen vacancies may range from 600 to 800 nm. In one embodiment, the source excitation is produced by a pulse or continuous wave (CW) laser.

In further detail, still referring to the invention of FIGS. 1(a), 1(b) and 1(c), the nanoparticle emitter 12 of the single-photon generator is a nanometer-sized photoluminescent particle. The dimensions of the metamaterial 14 can be varied in a wide scale depending on certain applications. The photonic guiding structure can be represented by standard-size optical fiber. This single-photon generator can work stably under normal conditions. A special envelope is required in order to get rid of background radiation.

The construction details of the invention as shown in FIGS. 1(a), 1(b), and 1(c) are that diamond containing impurity-vacancy, for example, nitrogen-vacancy or silicon-vacancy color center may be used as the nanoparticle emitter 12. The metamaterial 14 can be constructed from nanostructured metallic and dielectric elements arranged in periodic, aperiodic or random arrays.

The advantages of the present invention include, without limitation, that this generator is a single-photon source in a broad wavelength range with comparatively high emission rate and it can work stably under preferable temperatures from −35° C. to +50° C.

A fabrication method to producing homogeneously fluorescent nanodiamonds with high yields can include various approaches. For example, dispersed nanodiamonds, just several nanometers in diameter, have been synthesized from carbon black by laser irradiation in water at room temperature and normal pressure. In another experiment, nanodiamonds have been made by using a microwave plasma torch technique with methane and Ar or N₂ as catalysts.

In the preferred embodiment, the powder obtained by high energy ball milling of fluorescent high pressure, high temperature diamond microcrystals was converted in a pure concentrated aqueous colloidal dispersion of highly crystalline ultra-small diamond nanoparticles with a mean size of less than or equal to 10 nm, (see example, “High yield fabrication of fluorescent nanodiamonds” by Boudou et al. in Nanotechnology, 2009 June; 20(23): 235602. The results open up avenues for the industrial cost-effective production of fluorescent nanodiamonds with well-controlled properties.

In another embodiment, nanodiamonds powder (mean size of 35 nm) was bombarded by helium He²⁺ particles with energy of about 40 KeV at a dose of ˜1×10¹³ ions cm⁻². This procedure was followed by annealing for 2 hours at 800° C.

In another embodiment of the invention, the thin diamond film, having thickness of up to 1,000 nm was deposited by Chemical Vapor Deposition (CVD), using electron beam evaporation. The source material was evaporated in a vacuum, which allowed vapor particles to travel directly to the target object (substrate), where they condensed back to a solid state.

The diamond nitrogen-vacancy centers in all above described examples of preferred embodiments were located up to 1,000 nm away from the diamond surface.

Both CW and pulsed pumping can be used for the diamond excitation. It is important that the excitation wavelength is always shorter than the emission range. In particular, we have used pulsed laser at 465 nm wavelength with the energy of 10 mW and CW laser generating at 488 nm with the energy of 0.5 mW to produce emission in the range of 580-800 nm. The excitation could be done using a focused beam (focused with conventional lens) or with a tapered fiber, or an optical waveguide.

Single photon emission produced by diamonds requires further enhancement. It can be done using metamaterials with hyperbolic dispersion. In one embodiment of the invention, the nanodiamond is attached to the surface of the metamaterial by a spin coating procedure. This method is typically used for deposition of uniform thin films on flat substrates. According to this technique, an excess amount of a solution is placed on the substrate, which is then rotated at high speed in order to spread the fluid by centrifugal force.

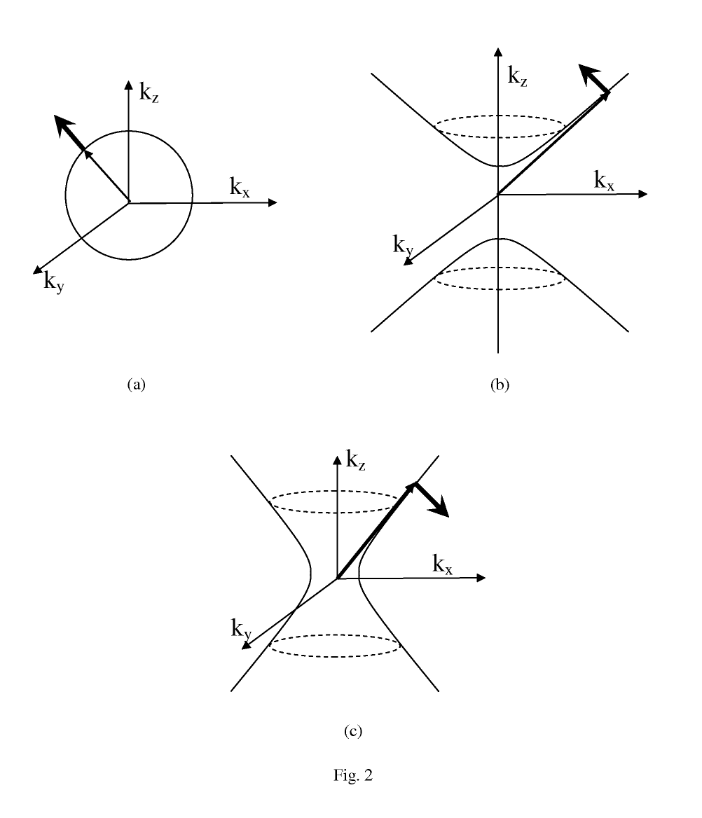

Metamaterials with hyperbolic dispersion, also known as indefinite media lie at the heart of devices such as the hyperlens and non-magnetic negative index waveguides. In an isotropic medium, the dispersion relation defines a spherical iso-frequency surface in the k-space (see FIG. 2(a)), thus placing an upper cut for the wavenumber 20, so that high wavevector modes 21 simply decay away. In contrast to this behavior, a strongly anisotropic metamaterial where the components of the dielectric permittivity tensor have opposite signs in two orthogonal directions can support bulk propagating waves with unbounded wavevectors. This can be most clearly seen in the case of uniaxial anisotropy where the dispersion relation for the extraordinary (TM-polarized) waves is described by hyperboloids of revolution around the symmetry axis z (see FIGS. 2(b) and 2(c)) and thus the dispersion does not limit the magnitude of the wavenumber at 20, which can be much larger instead.

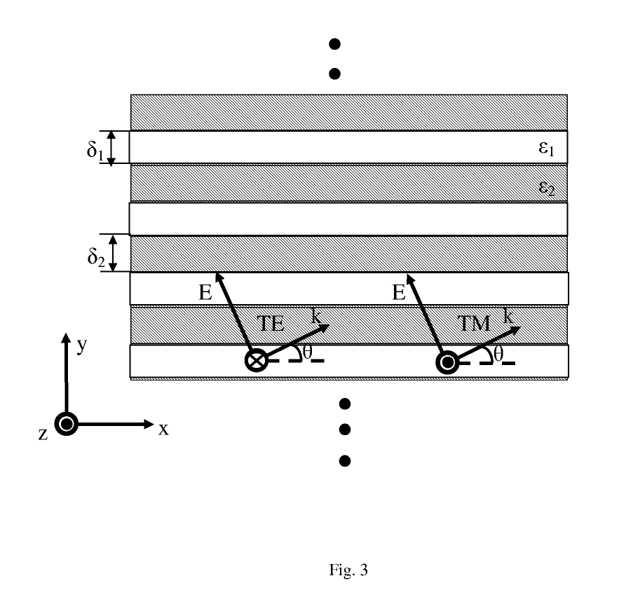

When dimensions of structural elements are much smaller than the free space wavelength, the effective permittivity of the metamaterial structures are evaluated by various homogenization techniques, where a given actual metamaterial is substituted by a virtual effective medium characterized by effective parameters. FIG. 3 illustrates the structure of a metamaterial with hyperbolic dispersion comprising a one-dimensionally periodic layered construction. The permittivities of the metal and dielectric layers are denoted respectively as ∈₁ and ∈₂, and the thicknesses as δ₁ and δ₂. All the layers are parallel to the x-z plane. Thus for such media, components (e₁, e₂, e₃) define the effective permittivity tensor ∈=diag(e₁, e₂, e₃). Similar to natural materials, depending on the relationship between e₁, e₂, e₃ the effective media are characterized as isotropic, e₁=e₂=e₃; biaxial, e₁¹ e₂¹ e₃, or uniaxial, e₁¹ (e₂=e₃). Another example of a hyperbolic metamaterial can consist of plasmonic nanowires embedded in a dielectric host. Such metamaterial can be similarly described by using the effective parameters, as mentioned above.

Hyperbolic dispersion requires that the sign of the real part of at least one of (e₁, e₂, e₃) would differ from the signs of the real parts of remaining two components. Depending on the signs of the real part of components (e₁, e₂, e₃), HMMs can be classified into two major groups: transverse positive (TP, Re(e₁)<0, Re(e₂)>0, Re(e₃)>0) and transverse negative (TN, Re(e₁)>0, Re(e₂)<0, Re(e₃)<0). The optic axis of either TP or TN hyperbolic metamaterial is perpendicular to the paired transverse components of the same sign.

The simplest transverse positive and transverse negative HMMs are uniaxial e₁¹ (e₂=e₃) with the two exemplary structures used to design HMMs being metal-dielectric lamellar composites and subwavelength-periodic arrays of metallic nanowires. Between these two structures, planar multilayer structures are easier to fabricate as submicron thickness samples.

A variety of techniques can be used to build the hyperbolic metamaterial. In the preferred embodiment, a practical realization of a hyperbolic metamaterial consisting of alternate layers of silver, Ag (∈ₛᵢₗᵥₑᵣ=−2.4+0.48i) and alumina, Al₂O₃ (∈ₐₗᵤₘᵢₙₐ=2.7) at a wavelength of λ=365 nm. In at least one embodiment, the system consists of 8 layers, each of thickness a=8 nm which is easily achievable by current fabrication techniques known to a person skilled in the art. The proposed device based on hyperbolic metamaterials is compatible with a wide variety of sources and capable of room temperature operation due to the broad bandwidth enhancement of spontaneous emission and directional photon emission.

The proposed single photon generator may be utilized in a variety of commercial, scientific and industrial applications, including, but not limited to: quantum cryptography; quantum computers; random number generators, both for quantum and for conventional computers; nanochemistry to control chemical reactions at the level of individual molecules; biochemical analysis to determine dynamics of molecular configuration, decoding DNA, obtaining information on nanostructure and status of nano devices; spectroscopy and material science to measure weak photon absorption.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention.

What is claimed is:

1. A system for producing emission of photon flux, comprising:
a source of an initial single photon flux, positioned at the interface of a metamaterial with a hyperbolic dispersion;
said single photon source is pumped by a pumping source which resulted in emitting an initial single photon flux;
said metamaterial enhances the initial single photon flux,
said metamaterial is attached to an optical output producing photon emission at a higher photon emission rate compared to said initial photon flux, wherein the output photon emission is 10-10000 times higher than the initial photon flux.

2. The system according to claim 1, wherein the output photon emission is in a broad spectral range from 600 to 800 nm.

3. The system according to claim 1, wherein said source of initial single photon flux operates at temperatures above −35° C. and below +50° C.

4. The system according to claim 1, wherein said initial single photon flux is emitted by a diamond structure comprising at least one impurity-vacancy color center.

5. The system according to claim 4, wherein a distance between the vacancy center in said diamond structure and said metamaterial interface is less than 1,000 nm.

6. The system according to claim 4, wherein said impurity comprises nitrogen.

7. The system according to claim 4, wherein said impurity comprises silicon.

8. The system according to claim 4, wherein the pumping source performs electrical pumping.

9. The system according to claim 4, wherein said diamond structure is used in a form of a diamond film.

10. The system according to claim 4, wherein said diamond structure comprises nanodiamond particle having size of up to 100 nm.

11. The system according to claim 1, wherein the system is implemented in a quantum computer.

12. The system according to claim 1, wherein said metamaterial comprises uniaxial optical anisotropy.

13. The system according to claim 12, wherein said metamaterial is transverse positive with an optical axis being oriented normally to the material interface.

14. The system according to claim 12, wherein said metamaterial comprises alternate layers of plasmonic and dielectric materials.

15. The system according to claim 14, wherein at least one layer is thinner than 100 nm.

16. The system according to claim 14, wherein said plasmonic material comprises at least one layer of silver.

17. The system according to claim 14, wherein said plasmonic material comprises at least one layer of transparent conducting oxide.

18. The system according to claim 14, wherein said dielectric material comprises alumina.

19. The system according to claim 14, wherein said plasmonic material comprises at least one layer of transition metal nitride.

20. A method for producing an emission of photon flux, comprising:
emitting initial single photon flux, enhancing said photon flux by a metamaterial with hyperbolic dispersion resulting in a photon emission with at least 10 times higher rate compared to said initial photon flux.

21. The method according to claim 20, wherein the emission of said initial single photon flux is generated by a diamond structure comprising at least one impurity-vacancy color center.

22. The method according to claim 20, wherein said diamond structure is attached to said metamaterial by a spin coating procedure.
